(19) United States
(12) Patent Application Publication
(10) Pub. No.: US 2015/0243347 A1
(43) Pub. Date: Aug. 27, 2015

(54) SEMICONDUCTOR DEVICE PREVENTING MULTIWORD STATE

(71) Applicant: PS5 LUXCO S.A.R.L., Luxembourg (LU)

(72) Inventor: Junichi Hayashi, Tokyo (JP)

(21) Appl. No.: 14/422,333

(22) PCT Filed: Aug. 20, 2013
(86) PCT No.: PCT/JP2013/072636

§ 371 Date: Feb. 18, 2015

(30) Foreign Application Priority Data
Aug. 22, 2012 (JP) 2012-183070

(51) Int. Cl. G11C 11/408; H01L 25/18; H01L 23/48; G11C 11/4093

(52) U.S. Cl. CPC G11C 11/4087; G11C 11/4093; G11C 11/4082; H01L 25/18; H01L 23/481; G11C 11/4085

(57) ABSTRACT

To prevent a multiword state in which a plurality of word lines are active in a same memory bank, the semiconductor device includes a plurality of memory chips commonly receiving an access command, in which each of the plurality of memory chips are provided with a control circuit ignoring an new access command when the bank address information in the new access command is the same as the bank address information for the specified memory bank even if the new access command received before reading/writing data from/to the specified memory bank of the selected memory chip is completed contains chip selection information selecting another memory chip.

### CROSS REFERENCE TO RELATED APPLICATIONS

This application is based on and claims the benefit of priority from Japanese Patent Application No. 2012-183070, filed on Aug. 22, 2012, the content and teachings of which are incorporated herein by reference.

### TECHNICAL FIELD

The present invention relates to a semiconductor device, particularly a semiconductor device provided with a plurality of memory banks.

### BACKGROUND ART

JP 2011-253607 A (Patent Document 1) describes one example of a semiconductor device provided with a plurality of memory banks. The semiconductor device disclosed in Patent Document 1 has first to fourth memory chips, each of which is provided with first to fourth memory banks.

### CITATION LIST

### Patent Literature

Patent Document 1: JP 2011-253607A

### SUMMARY OF INVENTION

### Technical Problem

In the semiconductor devices provided with a plurality of memory banks, like Patent Document 1, for example, the first memory bank of the first memory chip and the first memory bank of the second memory chip are selected by common bank address information. In such semiconductor devices, after an access command selecting the first memory bank of the first memory chip is input, in other words, while the first memory bank of the selected first memory chip is being active, both the first memory bank of the first memory chip and the first memory bank of the second memory chip that are specified by the same bank address information are active, i.e. in a multiword state if an illegal access command selecting the first memory bank of the second memory chip is input.

### Solution to Problem

A semiconductor device according to one embodiment includes: a plurality of memory chips commonly receiving an access command containing chip selection information and bank address information, in which

each of the plurality of memory chips includes a control circuit reading/writing data from/to a memory bank specified by the bank address information when the chip selection information selects the memory chip itself, and

the control circuit in each of the other memory chips than the memory chip selected by the chip selection information ignores an new access command when the bank address information in the new access command is the same as the bank address information for the specified memory bank even if the new access command received before completing reading/writing data from/to the specified memory bank of the selected memory chip contains chip selection information selecting the other memory chip.

### Advantageous Effects of Invention

According to the semiconductor device of this embodiment, in the semiconductor device provided with a plurality of memory chips having a memory bank specified by a same bank address information, the other memory chips than the selected memory chip ignores an access command when the access command received before reading/writing data from/to the specified memory bank of the selected memory chip is completed, in other words, while the specified memory bank of the selected memory chip is being active contains the same bank address information for the specified memory bank. Accordingly, a multiword state in which a plurality of word lines is active in a memory bank specified by common bank address information can be prevented.

### BRIEF DESCRIPTION OF DRAWINGS

FIG. 1 shows a block diagram illustrating a semiconductor device according to the first embodiment of the present invention.

FIG. 2 shows a block diagram illustrating a bank active control circuit used in the semiconductor device shown in FIG. 1.

FIG. 3 shows a block diagram illustrating a bank selection control circuit used in the semiconductor device shown in FIG. 1.

FIG. 4 shows a circuit diagram illustrating a bank active guard signal generation circuit used for the bank active control circuit shown in FIG. 2.

FIG. 5 shows a circuit diagram illustrating a bank active signal generation circuit used for the bank selection control circuit shown in FIG. 3.

FIG. 6 shows a waveform chart explaining the operation of the semiconductor device shown in FIG. 1.

FIG. 7 shows a block diagram illustrating a semiconductor device according to the second embodiment of the present invention.

FIG. 8 shows a circuit diagram illustrating a command detection circuit in a chip address comparison circuit used in the semiconductor device shown in FIG. 7.

FIG. 9 shows a block diagram illustrating a bank selection control circuit used in the semiconductor device shown in FIG. 7.

FIG. 10 shows a circuit diagram illustrating a bank active guard signal generation circuit used for the bank active control circuit shown in FIG. 9.

FIG. 11 shows a circuit diagram illustrating one example of the data latch circuit used for the bank active guard signal generation circuit shown in FIG. 10.

FIG. 12 shows a circuit diagram illustrating another example of the data latch circuit used for the bank active guard signal generation circuit shown in FIG. 10.

FIG. 13 shows a waveform chart explaining the operation of the semiconductor device shown in FIG. 7.

FIG. 14 shows a cross-sectional view illustrating a semiconductor device according to the first embodiment of the present invention.

FIG. 15 shows a cross-sectional view illustrating a semiconductor device according to the second embodiment of the present invention.

### DESCRIPTION OF EMBODIMENTS

In this embodiment, the semiconductor device refers to DRAM (dynamic random access memory). However, the present invention is not limited to DRAM and may be other semiconductor devices (SRAM (static random access memory), PRAM (phase change random access memory), flash memory, etc.).

### First Embodiment

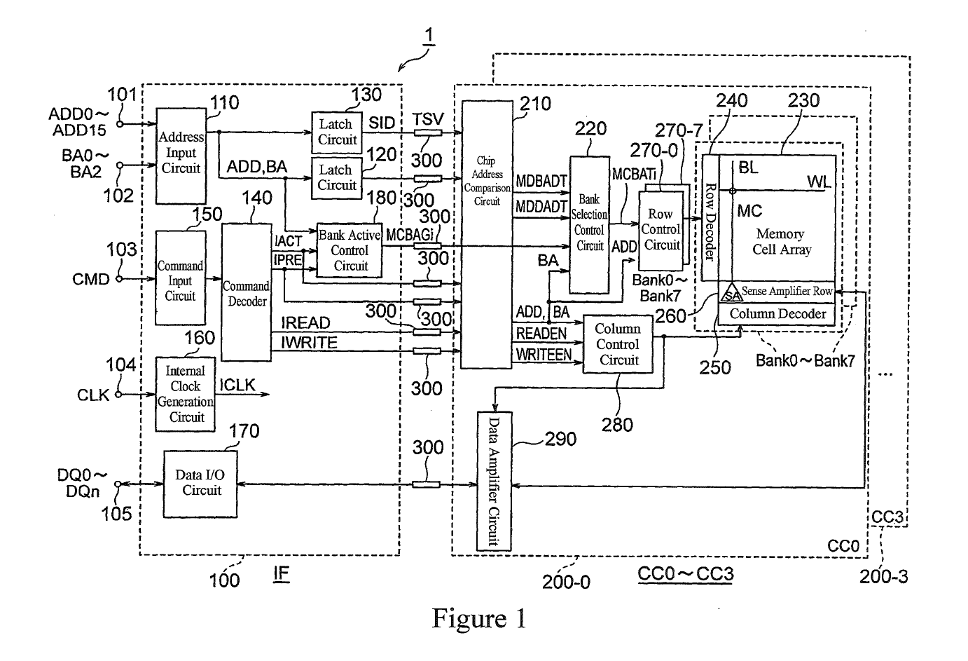

FIG. 1 shows a block diagram illustrating a semiconductor device 1 according to the first embodiment of the present invention. The semiconductor device 1 as this figure shows consists of a semiconductor chip (IF) 100 and a plurality of memory chips (CC0 to CC3) 200-0 to 200-3. In the example shown in this figure, the semiconductor device 1 has first to fourth memory chips (CC0 to CC3) 200-0 to 200-3 as the plurality of memory chips.

The semiconductor chip (IF) 100 are a control chip controlling the first to the fourth memory chips (CC0 to CC3) 200-0 to 200-3.

The semiconductor chip (IF) 100 is provided with an address pad 101 and a bank address pad 102 that receive 16-bit address signals ADD0 to ADD15 and 3-bit bank address signals (bank address information) BA0 to BA2, respectively. The 16-bit address signals ADD0 to ADD15 and the 3-bit bank address signals (bank address information) BA0 to BA2 are input to the address input circuit 110. The 16-bit address signals ADD0 to ADD15 contains a chip address signal (chip selection information) SID identifying the first to the fourth memory chips (CC0 to CC3) 200-0 to 200-3.

In the example shown in FIG. 1, the chip address signal (chip selection information) SID consists of the 15th bit X14 and the 16th bit X15 as the high-order bits of the 16-bit address signal ADD0 to ADD15. The first memory chip (CC0) 200-0 is specified when X14=0 and X15=0. The second memory chip (CC1) 200-1 is specified when X14=1 and X15=0. The third memory chip (CC2) 200-2 is specified when X14=0 and X15=1. The fourth memory chip (CC3) 200-3 is specified when X14=1 and X15=1.

Hereinafter, the 16-bit address signals ADD0 to ADD15 are sometimes referred to only as “address signal ADD,” and the 3-bit bank address signals BA0 to BA2 (bank address information) as “bank address signal BA (bank address information).”

After output from the address input circuit 110, the chip address signal SID (chip selection information); and the address signal ADD and the bank address signal BA (bank address information) are time-controlled in the first and the second latch circuits 120, 130, respectively, and then commonly supplied to the first to the fourth memory chips (CC0 to CC3) 200-0 to 200-3 through the corresponding through electrodes (TSV) 300.

The command decoder 140 receives a command signal CMD input through a command pad 103 from the command input circuit 150. The command decoder 140 supplies an active command signal IACT, a precharge command signal IPRE, a read forward command signal IREAD, and a write command signal IWRITE to the first to the fourth memory chips (CC0 to CC3) 200-0 to 200-3 through the corresponding electrodes (TSV) 300 in response to the input command signal CMD.

The internal clock generation circuit 160 receives a clock signal CLK through a clock pad 104 and outputs an internal clock signal ICLK to each of the internal circuits. The internal clock signal ICLK is commonly supplied to the first to the fourth memory chips (CC0 to CC3) 200-0 to 200-3, which is not shown in the figures.

The data I/O circuit 170 receives (n+1)-bit data DQ0 to DQn read out from the respective memory cell arrays 230 (to be described later) of the first to the fourth memory chips (CC0 to CC3) 200-0 to 200-3 and outputs the received data to an input-output terminal 105 in read mode. On the other hand, the data I/O circuit 170 supplies (n+1)-bit data DQ0 to QQn received from the data input-output terminal 105 to the first to the fourth memory chips (CC0 to CC3) 200-0 to 200-3 in write mode.

The bank active control circuit 180 activates the (i+1) th bank active guard signal MCBAGi (bank state information) in accordance with the 3-bit bank address signal (bank address information) BA0 to BA2 and the active command signal IACT and outputs the activated signal to each of the memory chips (CC0 to CC3) 200-0 to 200-3. The (i+1)th bank active guard signal MCBAGi is deactivated in accordance with the precharge command signal IPRE. In the example shown in FIG. 1 is 0≦i≦7.

Since the first to the fourth memory chips (CC0 to CC3) 200-0 to 200-3 have a same configuration, FIG. 1 shows the configuration of only the first memory chip (CC0) 200-0 and does not the other memory chips (CC1 to CC3) 200-1 to 200-3.

The chip address comparison circuit 210 mounted on each of the memory chips has its own chip information. When the chip address signal SID (chip selection information) is the same as the chip information, the chip address comparison circuit 210 outputs a control signal (to be described later), the address signal ADD and the bank address signal BA (bank address information). The chip information varies among the first to the fourth memory chips (CC0 to CC3) 200-0 to 200-3.

The chip address comparison circuit 210 also outputs an active flag signal MDBADT, a precharge flag signal MDDADT, a read enable signal READEN, and a write enable signal WRITEEN as the above-mentioned control signal. The active flag signal MDBADT is output in response to an active command signal IACT. The precharge flag signal MDDADT is output in response to a precharge command signal IPRE. The read enable signal READEN is output in response to a read command signal IREAD. The write enable signal WRITEEN is output in response to a write command signal IWRITE.

The bank selection control circuit 220 activates the (i+1)th bank active signal MCBATi in accordance with the active flag signal MDBADT and the bank address signal BA (bank address information) when the (i+1)th bank active guard signal MCBAGi is inactive. On the other hand, when the (i+1)th bank active guard signal MCBAGi is active, the bank selection control circuit 220 does not activate the (i+1)th bank active signal MCBATi and remain the (i+1)th bank active guard signal inactive even if receiving an active flag signal MDBADT and a bank address signal BA (bank address information).

For example, the first to the fourth memory chips (CC0 to CC3) 200-0 to 200-3 commonly receive an access command ACT containing a chip address signal SID (chip selection information), an active command signal IACT, an address signal ADD, and a bank address signal BA (bank address information), where the access command ACT specifies the first memory bank Bank0 of the first memory chip (CC0) 200-0. In this case, the bank selection control circuit 220 of the first memory chip (CC0) 200-0 activates the first bank active signal MCBAT0 to access the first memory bank Bank0.

On the other hand, the bank active control circuit 180 in the control chip IF activates the first bank active guard signal MCBAG0 in accordance with the bank address signal BA (bank address information) contained in an access command ACT and the active command signal IACT activated in response to the access command ACT and then commonly supplies the activated first bank active guard signal MCBAG0 to the respective bank selection control circuits 220 of the first to the fourth memory chips (CC0 to CC3) 200-0 to 200-3. As a result, the respective bank selection control circuits 220 of the first to the fourth memory chips (CC0 to CC3) 200-0 to 200-3 ignore a new access command ACT without newly activating the bank active signal MCBAT0 even if receiving the new access command ACT containing the bank address information BA specifying the first memory bank Bank0 while the first bank active guard signal MCBAG0 is being activated. Accordingly, a multiword state in which a plurality of word lines WL is active in a memory bank specified by common bank address information can be prevented.

In the example shown in FIG. 1, each of the first to the fourth memory chips (CC0 to CC3) 200-0 to 200-3 is provided with first to eighth memory banks Bank0 to Bank7 as a memory part. Since the first to the eighth memory banks Bank0 to Bank7 have a same configuration, FIG. 1 shows the configuration of only the first memory bank Bank0 and does not the other memory banks Bank1 to Bank7.

Each of the memory banks include memory cell arrays 230, each of which has a number of memory cells MC memorizing 1 bit arranged in a matrix in the row and the column directions, a row decoder 240 selecting one word line WL associated with a specified row address, and a column decoder 250 selecting one bit line BL associated with a specified column address through a sense amplifier row 260.

In other words, a plurality of word lines WL intersect with a plurality of bit lines BL in each of the memory cell arrays 230, in which memory cells MC are arranged at the intersections. FIG. 1 only shows one word line WL, one bit line BL, and one memory cell MC. The bit lines BL are each connected with the sense amplifier SA of the corresponding sense amplifier row 260.

Each of the first to the fourth memory chips (CC0 to CC3) 200-0 to 200-3 has first to eighth row system control circuits 270-0 to 270-7 corresponding to the first to the eighth memory banks Bank0 to Bank7. The first to the eighth row control circuits 270-0 to 270-7 generate a row address associated with the corresponding first to the eighth memory bank Bank0 to Bank7, respectively, in accordance with the address signal ADD and the first to the eighth bank active signals MCBAT0 to MCBAT7, respectively. This generated row address is supplied to the row decoder 240.

The column control circuit 280 generates a column address based on the address signal ADD, the bank address signal BA, the read enable signal READEN, and the write enable signal WRITEEN. This generated column address is supplied to the column decoder 250.

The data amplifier circuit 290 is mounted between the data I/O circuit 170 and the sense amplifier row 260 of each of the memory banks Bank0 to Bank7 of the memory part to read and write data from and to each of the memory banks Bank0 to Bank7 of the memory part.

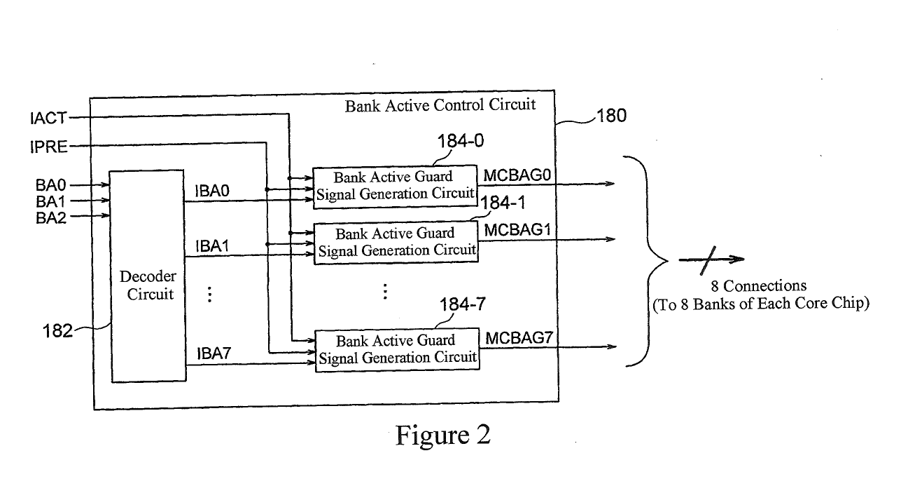

FIG. 2 shows a block diagram illustrating the bank active control circuit 180.

The bank active control circuit 180 has a decoder circuit 182 receiving 3-bit bank address signals (bank address information) BA0, BA1, and BA2 and outputting first to eighth internal bank address signals IBA0 to IBA7 identifying the memory banks; and first to eighth bank active guard signal generation circuits 184-0 to 184-7 corresponding to the first to the eighth memory banks Bank0 to Bank7.

The first to the eighth bank active guard signal generation circuits 184-0 to 184-7 activate the first to the eighth bank active guard signals MCBAG0 to MCBAG7, respectively, when an active command signal IACT and the first to eighth internal bank address signals IBA0 to IBA7 are activated, respectively. The first to the eighth bank active guard signals MCBAG0 to MCBAG7 output from the bank active control circuit 180 are commonly supplied to the first to the fourth memory chips (CC0 to CC3) 200-0 to 200-3.

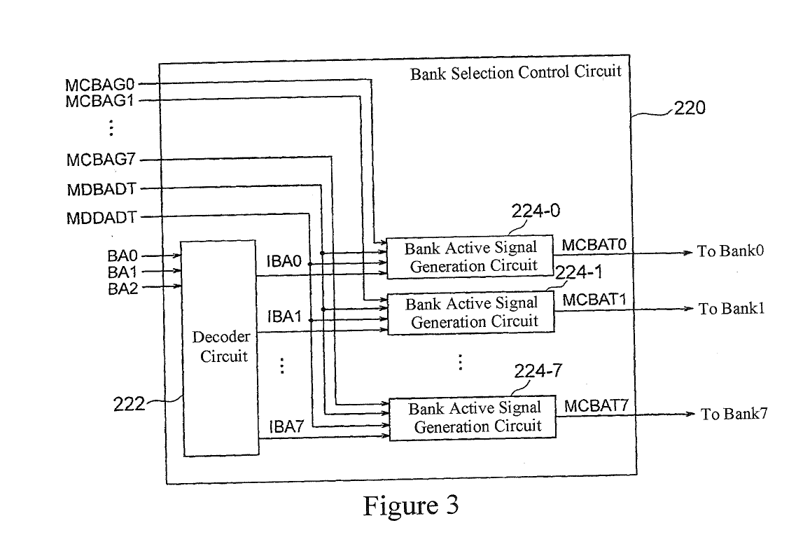

FIG. 3 shows a block diagram illustrating the bank selection control circuit 220.

The bank selection control circuit 220 has a decoder circuit 222 receiving 3-bit bank address signals (bank address information) BA0, BA1, and BA2 and outputting first to eighth internal bank address signals IBA0 to IBA7 identifying the memory banks; and first to eighth bank active signal generation circuits 224-0 to 224-7 corresponding to the first to the eighth memory banks Bank0 to Bank7.

The first to the eighth bank active signal generation circuits 224-0 to 224-7 activates the first to the eighth bank active signals MCBAT0 to MCBAT7, respectively, if the first to eighth bank active guard signals MCBAG0 to MCBAG7 are inactive, respectively, when the active flag signal MDBADT and the first to eighth internal bank address signals IBA0 to IBA7 are activated, respectively.

On the other hand, when the first to eighth bank active guard signals MCBAG0 to BCBAG7 are active, respectively, the first to the eighth bank active signal generation circuits 224-0 to 224-7 remain the first to the eighth bank active signal MCBAT0 to MCBAT7 inactive, respectively, even if the active flag signal MDBADT and the first to eighth internal bank address signals IBA0 to IBA7 are activated, respectively.

For example, in the case where the bank active control circuit 180 of the control chip IF activates the first bank active guard signal MCBAG0 in accordance with the access command ACT containing the bank address information specifying the first memory bank BANK0, the first bank active signal generation circuit 224-0 of each of the memory chips does not activate the first bank active signal MCBAT0 even if the first internal bank address signal IBA0 and the active flag signal MDBADT are activated in accordance with a new access command while the first bank active guard signal MCBAG0 is being active.

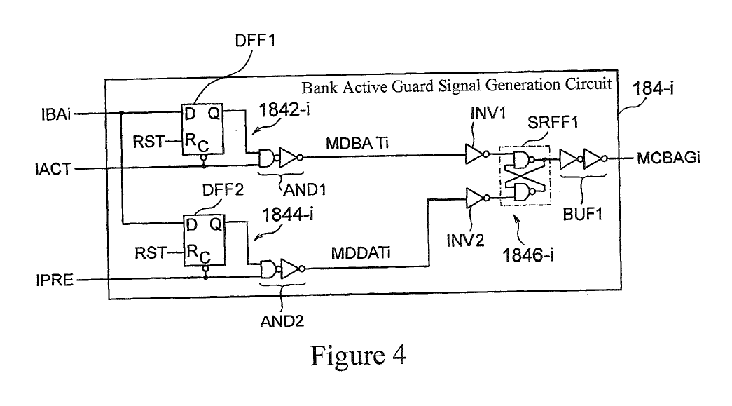

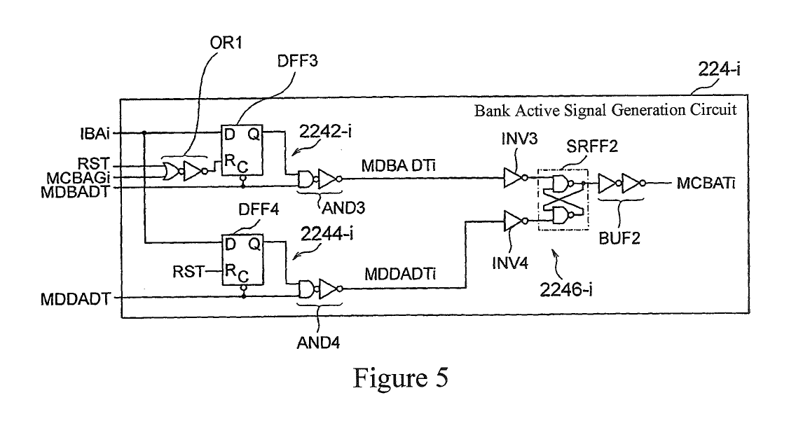

FIGS. 4 and 5 show a circuit diagram illustrating the (i+1)th bank active guard and the (i+1)th signal generation circuit 184-i and the bank active signal generation circuit 224-i, respectively.

As FIG. 4 shows, the (i+1)th bank active guard signal generation circuit 184-i consists of an (i+1)th bank active flag signal generation circuit 1842-i generating an (i+1)th bank active flag signal MDBATi from an active command signal IACT and an (i+1)th internal bank address signal IBAi; an (i+1)th bank precharge flag signal generation circuit 1844-i generating a bank precharge signal MDDATi from a precharge signal IPRE and an (i+1)th internal bank address signal IBAi; and an (i+1)th bank active guard signal generation circuit 1846-i generating an (i+1)th bank active guard signal MCBAGi from an (i+1)th bank active flag signal MDBATi and an (i+1)th bank precharge flag signal MDDATi.

Specifically, the (i+1)th bank active flag signal generation circuit 1842-i consists of a D-type flip-flop DFF1 and an AND gate AND1 formed from a combination of a NAND gate and an inverter. In the D-type flip-flop DFF1, the data input terminal D receives an (i+1)th internal bank address signal IBAi, the reset input terminal R receives a reset signal RST, and the clock input terminal C receives an active command signal IACT. The AND gate AND1 performs logical conjunction on the output signal output from the output terminal D of the D-type flip-flop DFF1 and the active command signal IACT and outputs the logical conjunction result signal as an (i+1)th bank active flag signal MDBATi.

As well as the (i+1)th bank active flag signal generation circuit 1842-i, the (i+1)th bank precharge flag signal generation circuit 1844-i consists of a D-type flip-flop DFF2 and an AND gate AND2 formed from a combination of a NAND gate and an inverter. In the D-type flip-flop DFF2, the data input terminal D receives an (i+1)th internal bank address signal IBAi, the reset input terminal R receives a reset signal RST, and the clock input terminal C receives a precharge signal IPRE. The AND gate AND2 performs logical conjunction on the output signal output from the output terminal D of the D-type flip-flop DFF2 and the precharge signal IPRE and outputs the logical conjunction result signal as an (i+1)th bank precharge flag signal MDDATi.

The (i+1)th bank active guard signal generation circuit 1846-i consists of a first inverter INV1; a second inverter INV2; an SR-type flip-flop SRFF1 formed from two NAND gates; and a buffer gate BUF1 in which two inverters are cascade-arranged. The first inverter INV1 inverts the (i+1)th bank active flag signal MDBATi and outputs the inverted (i+1)th bank active flag signal. The second inverter INV2 inverts the (i+1)th bank precharge flag signal MDDATi and outputs the inverted (i+1)th bank precharge flag signal. In the SR-type flip-flop SRFF1, the set input terminal receives the inverted (i+1)th bank active flag signal, and the reset input terminal receives the inverted (i+1)th bank precharge flag signal. The buffer gate BUF1 amplifies the output signal from the SR-type flip-flop SRFF1 and outputs the amplified signal as an (i+1)th bank active guard signal MCBAGi.

As FIG. 5 shows, the (i+1)th bank active signal generation circuit 224-i consists of an (i+1)th bank active flag signal generation circuit 2242-i generating an (i+1)th bank active flag signal MDBADTi from an active flag signal MDBADT, an (i+1)th bank active guard signal MCBAGi, and an (i+1)th internal bank address signal IBAi; an (i+1)th bank precharge flag signal generation circuit 2244-i generating a (i+1)th bank precharge signal MDDADTi from a precharge flag signal MDDADT and an (i+1)th internal bank address signal IBAi; and an (i+1)th bank active signal generation circuit 2246-i generating an (i+1)th bank active signal MCBATi from an (i+1)th bank active flag signal MDBADTi and an (i+1)th bank precharge flag signal MDDADTi.

Specifically, the (i+1)th bank active flag signal generation circuit 2242-i consists of an OR gate OR1 formed from a combination of an NOR gate and an inverter, a D-type flip-flop DFF3, and an AND gate AND3 formed from a combination of a NAND gate and an inverter. The OR gate OR1 performs logical addition on the reset signal and the (i+1)th bank active guard signal MCBAGi and outputs the logical addition result signal. In the D-type flip-flop DFF3, the data input terminal D receives an (i+1)th internal bank address signal IBAi, the reset input terminal R receives a logical addition result signal, and the clock input terminal C receives an active flag signal MDBADT. The AND gate AND3 performs logical conjunction on the output signal output from the output terminal D of the D-type flip-flop DFF3 and the active flag signal MDBADT and outputs the logical conjunction result signal as an (i+1)th bank active flag signal MDBADTi.

The (i+1)th bank precharge flag signal generation circuit 2244-i consists of a D-type flip-flop DFF4 and an AND gate AND4 formed from a combination of a NAND gate and an inverter. In the D-type flip-flop DFF4, the data input terminal D receives an (i+1)th internal bank address signal IBAi, the reset input terminal R receives a reset signal RST, and the clock input terminal C receives a precharge flag signal MDDADT. The AND gate AND4 performs logical conjunction on the output signal output from the output terminal D of the D-type flip-flop DFF4 and the precharge flag signal MDDADT and outputs the logical conjunction result signal as an (i+1)th bank precharge flag signal MDDADTi.

The (i+1)th bank active signal generation circuit 2246-i consists of a first inverter INV3; a second inverter INV4; an SR-type flip-flop SRFF2 formed from two NAND gates; and a buffer gate BUF2 in which two inverters are cascade-arranged. The first inverter INV3 inverts the (i+1)th bank active flag signal MDBADTi and outputs the inverted (i+1)th bank active flag signal. The second inverter INV4 inverts the (i+1)th bank precharge flag signal MDDADTi and outputs the inverted (i+1)th bank precharge flag signal. In the SR-type flip-flop SRFF2, the set input terminal receives the inverted (i+1)th bank active flag signal, and the reset input terminal receives the inverted (i+1)th bank precharge flag signal. The buffer gate BUF2 amplifies the output signal from the SR-type flip-flop SRFF2 and outputs the amplified signal as an (i+1)th bank active signal MCBATi.

The semiconductor device (1) according to the first embodiment includes: a plurality of memory chips (200-0 to 200-3) commonly receiving an access command (ACT) containing chip selection information (SID) and bank address information (BA), in which

each of the plurality of memory chips (200-0 to 200-3) includes a control circuit (220) reading/writing data from/to a memory bank (Bank0 to Bank7) specified by the bank address information (BA) when the chip selection information (BA) selects the memory chip itself, and

the control circuit in each of the other memory chips than the memory chip (220) selected by the chip selection information (SID) ignores an new access command when the bank address information (BA) in the new access command is the same as the bank address information for the specified memory bank even if the new access command received before reading/writing data from/to the specified memory bank of the selected memory chip is completed contains chip selection information (SID) selects the memory chip itself.

The control circuit (220) of each of the other memory chips maintains the bank state information (MCBAGi) on a specified memory bank in the selected memory chip and ignores a new access command (ACT) while the bank state information (MCBAGi) shows that the specified memory bank in the selected memory chip is active.

The semiconductor device (1) according to the first embodiment further includes a control chip (100) commonly outputting an access command (ACT) to a plurality of memory chips (200-0 to 200-3), in which

the control chip (100) has a control signal generation circuit (180) outputting the bank state information (MCBAGi) to the control circuit (220) of each of the plurality of memory chips (200-0 to 200-3) in accordance with the access command (ACT).

The control signal generation circuit (180) resets the bank state information (MCBAGi) in accordance with the precharge command (IPRE) containing the bank address information (BA) for the specified memory bank.

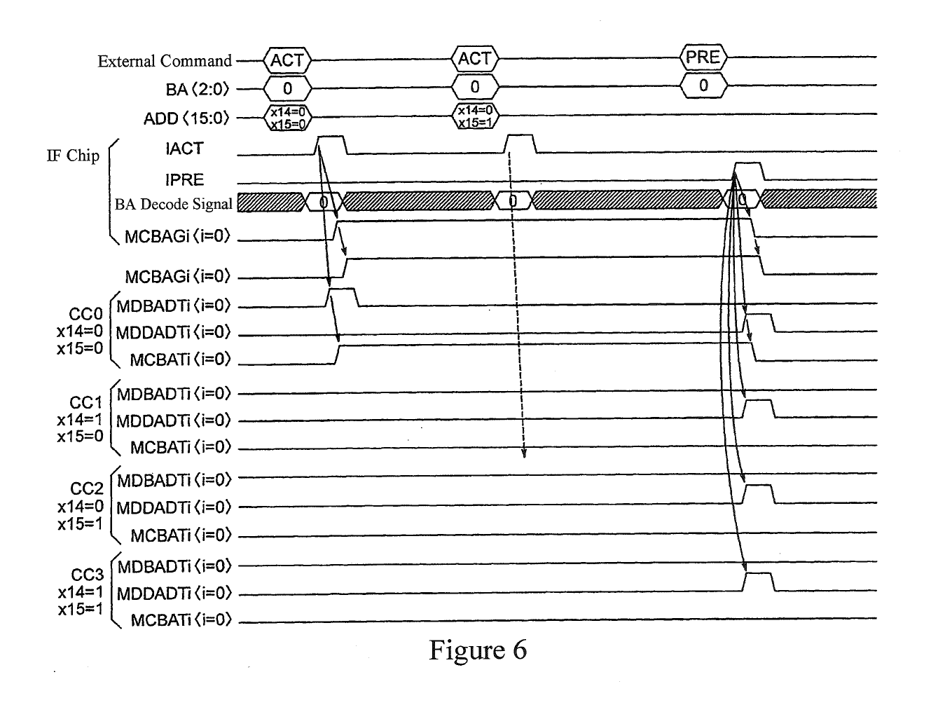

FIG. 6 shows a waveform chart explaining the operation of the semiconductor device 1 shown in FIG. 1.

For example, when the respective first memory banks Bank0 of all the first to the fourth memory chips (CC0 to CC3) 200-0 to 200-3 are not selected, an access command ACT containing a bank address signal BA (bank address information) specifying the first memory bank Bank0 and a chip address signal SID (chip selection information) specifying the first memory chip (CC0) 200-0 is input from outside.

In this case, the semiconductor chip (IF) 100 activates the active command signal IACT in response to the access command ACT and commonly supplies the active command signal IACT to the first to the fourth memory chips (CC0 to CC3) 200-0 to 200-3. The chip address comparison circuit 210 in the first memory chip (CC0) 200-0 activates the active flag signal MDBADT in response to an active command signal IACT when the chip address signal SID (chip selection information) is the same as its own chip information. The bank active signal generation circuit 224-0 of the bank selection control circuit 220 in the first memory chip (CC0) 200-0 activates the first bank active flag signal MDBADT0 and the first bank active signal MCBAT0 in response to the active flag signal MDBADT and the bank address signal and accesses the first memory bank Bank0. The access command ACT also contains a row address signal specifying a word line to active the word line in the first memory bank Bank0 in the accessed first memory chip (CC0) 200-0 in accordance with the row address signal (not shown).

On the other hand, the bank active control circuit 180 activates the first bank active guard signal MCBAG0 in accordance with the access command ACT and outputs the first bank active guard signal MCBAG0 to the bank selection control circuit 220 of each of the memory chips. Activating the first bank active guard signal MCBAG0 is preferably time-controlled after the first bank active signal MCBAT0 is activated.

Next, when the first memory bank Bank0 of the first memory chip (CC0) 200-0 is selected, a new access command ACT containing a bank address signal BA (bank address information) specifying the first memory bank Bank0 and a chip address signal SID (chip selection information) specifying the third memory chip (CC2) 200-2 is input from outside before reading/writing data from/to the memory bank Bank0 of the first memory chip (CC0) 200-0 is completed.

In this case, the internal active command signal IACT is activated in the semiconductor chip (IF) 100. However, since the first bank active guard signal MABAG0 is active, the first memory bank Bank0 of the third memory chip (CC2) 200-2 remains inactive without activating the first bank active signal MCBAT0 of the third memory chip (CC2) 200-2.

The first bank active guard signal MCBAG0 is deactivated in accordance with the precharge command signal IPRE input from outside. In the first memory bank Bank0 in the first memory chip (CC0) 200-0, the word line that has been activated in accordance with the access command is deactivated in accordance with the precharge command.

Although not shown in the figures, a read or write command for the first memory bank Bank0 may be input before a precharge command IPRE. When the read and the write commands are input, no chip address signals SID (chip selection information) has not been specified. Thus, a memory chip that has already been activated is accessed when a command ACT is input.

The semiconductor device 1 according to the first embodiment of the present invention including a plurality of memory chips 200-0 to 200-3 commonly receiving an access command ACT, in which the plurality of memory chips 200-0 to 200-3 are provided with a control circuit 220 ignoring an new access command ACT when the bank address information BA in the new access command ACT is the same as the bank address information BA for the specified memory bank Bank0 even if the new access command ACT received before reading/writing data from/to the specified memory bank Bank0 of the selected memory chip 200-0 is completed contains chip selection information SID selecting another memory chip 200-2, can prevent a multiword state in which a plurality of word lines WL from being activated in the same memory bank Bank0.

### Second Embodiment

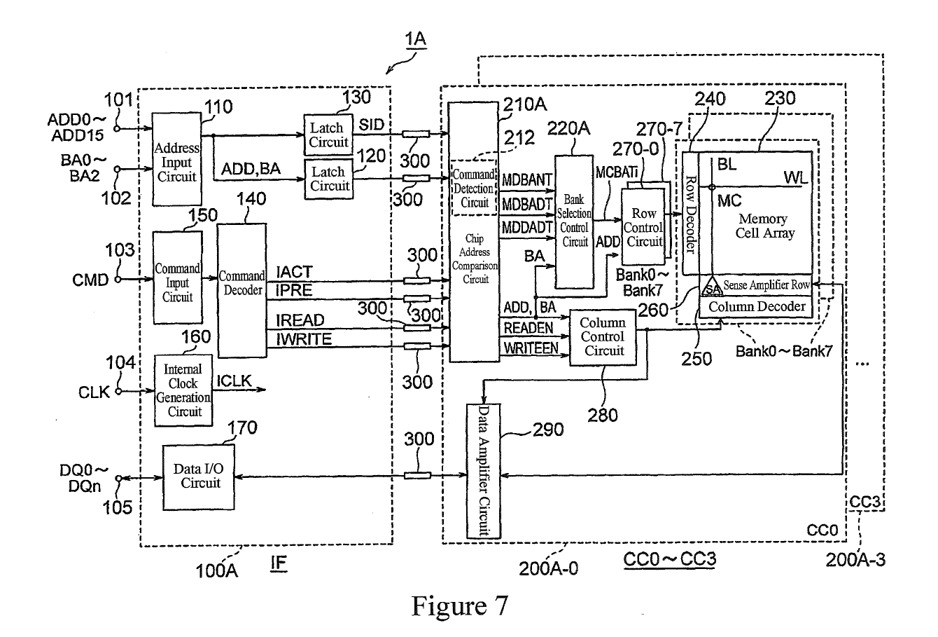

FIG. 7 shows a block diagram illustrating a semiconductor device 1A according to the second embodiment of the present invention.

The second embodiment is different from the above-mentioned first embodiment in that a bank active guard signal generation circuit is provided in each of the memory chips.

The same reference signs are assigned to the components having the same features as those in FIG. 1. Only the difference will be explained below to simplify the explanation.

The semiconductor device 1A consists of a semiconductor chip (IF) 100 and a plurality of first to fourth memory chips (CC0 to CC3) 200A-0 to 200A-3.

In the semiconductor device 1 according to the first embodiment shown in FIG. 1, the semiconductor chip (IF) (control chip) 100 is provided with a bank active control circuit 180.

On the other hand, in the semiconductor device 1A according to the second embodiment shown in FIG. 7, the semiconductor chip (control chip) (IF) 100A is not provided with a bank active control circuit 180.

In each of the first to the fourth memory chips (CC0 to CC3) 200A-0 to 200A-3, the chip address comparison circuit 210A is provided with a command detection circuit 212. Moreover, the bank selection circuit 220A of the semiconductor device 1A according to the second embodiment is different from the bank selection circuit 220 of the semiconductor device according to the first embodiment as described later.

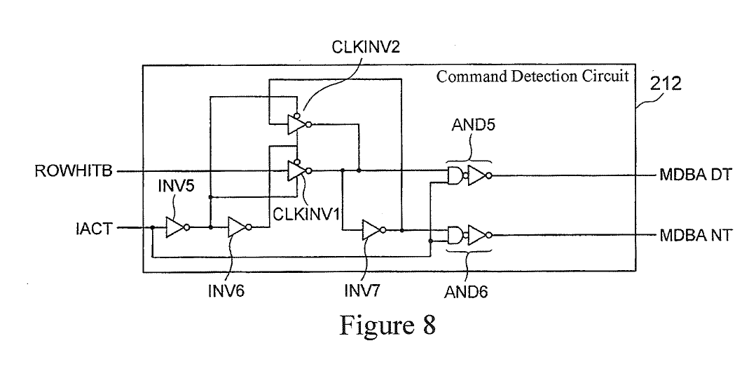

FIG. 8 shows a circuit diagram illustrating the command detection circuit 212 in the chip address comparison circuit 210A.

The control signal ROWHITB is activated when a chip address signal SID (chip selection information) is the same as the chip information held by each of the memory chips. The command detection circuit 212 activates the main active flag signal MDBADT when the control signal ROWHITB and the active command signal IACT are activated. The command detection circuit 212 also activates the auxiliary active flag signal MDBANT when the control signal ROWHITB is inactive but when the active command signal IACT is activated. In other words, in an unselected memory chip, the auxiliary active flag signal MDBANT is also activated when the active command signal IACT is activated.

Specifically, the command detection circuit 212 consists of a first inverter INV5, a second inverter INV6, a first clocked inverter CLKINV1, a second clocked inverter CLKINV2, a third inverter INV7, a first AND gate AND5 formed from a combination of a NAND gate and an inverter, and a second AND gate AND6 formed from a combination of a NAND gate and an inverter.

The first inverter INV5 inverts the active command signal IACT and outputs the inverted active command signal. The second inverter INV6 inverts the inverted active command signal and outputs the regenerated active command signal. The first clocked inverter CLKINV1 inverts the control signal ROWHITB and outputs the inverted control signal. The third inverter INV7 inverts the inverted control command signal and outputs the regenerated control command signal. The second clocked inverter CLKINV2 inverts the regenerated control signal and outputs this inverted control signal. The first AND gate AND6 performs logical conjunction on the inverted control signal output and the active command signal IACT and outputs the logical conjunction result signal as a main active flag signal MDBADT. The second AND gate AND5 performs logical conjunction on the regenerated control signal and the active command signal IACT and outputs the logical conjunction result signal as an auxiliary active flag signal MDBANT.

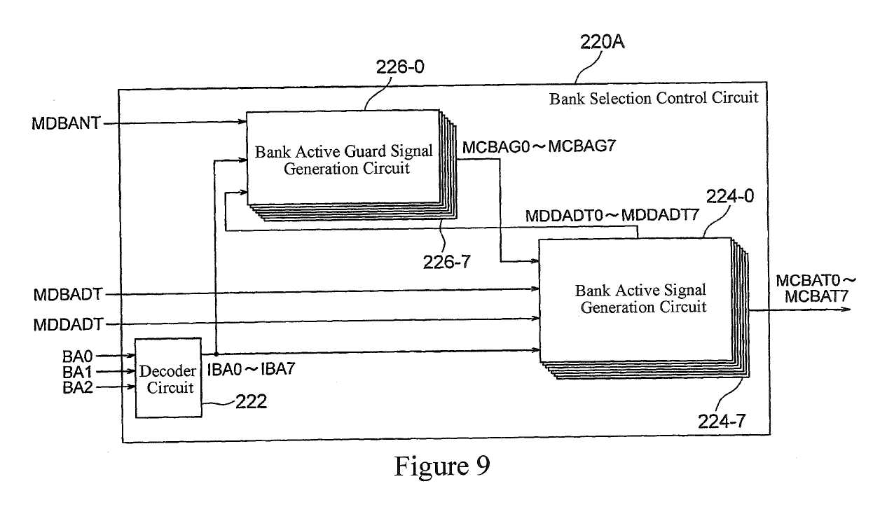

FIG. 9 shows a block diagram illustrating the bank selection control circuit 220A.

The bank selection control circuit 220A is provided with not only a decoder circuit 222 and first to eighth bank active signal generation circuits 224-0 to 224-7 but also first to eighth bank active guard signal generation circuits 226-0 to 226-7.

The first to the eighth bank active guard signal generation circuits 226-0 to 226-7 activate the first to the eighth bank active guard signals MCBAG0 to MCBAG7 in response to the first and the eighth internal bank address signals (BA0 to BA7), respectively, when an auxiliary active flag signal MDBANT is active.

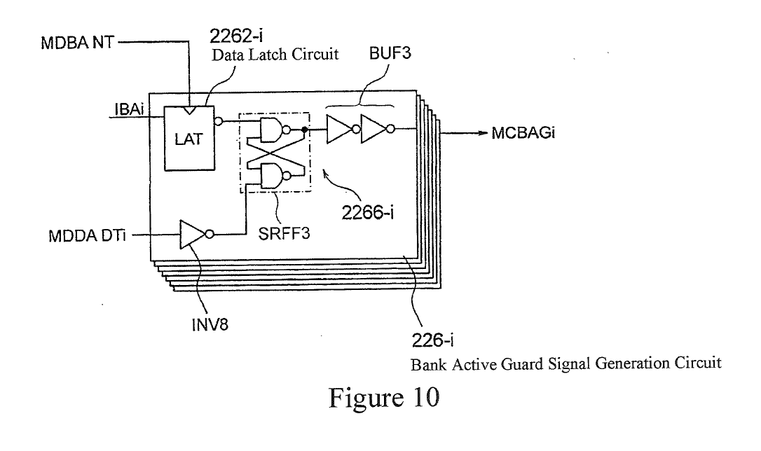

FIG. 10 shows a circuit diagram illustrating the (i+1)th bank active guard signal generation circuit 226-i.

The (i+1)th bank active guard signal generation circuit 226-i consists of an (i+1)th data latch circuit 2262-i latching the (i+1)th internal bank address signal IBAi in response to the auxiliary active flag signal MDBANT; and an (i+1)th bank active guard signal generation circuit 2266-i generating an (i+1)th bank active guard signal MCBAGi from the signal latched by the (i+1)th data latch circuit 2262-i and an (i+1)th bank precharge flag signal MDDADTi.

Specifically, the (i+1)th bank active guard signal generation circuit 2266-i consists of an inverter INV8; an SR-type flip-flop SRFF3 formed from two NAND gates; and a buffer gate BUF3 in which two inverters are cascade-arranged. The inverter INV8 inverts the (i+1)th bank precharge flag signal MDDADTi and outputs the inverted (i+1)th bank precharge flag signal. In the SR-type flip-flop SRFF3, the set input terminal receives the signal latched by the (i+1)th data latch circuit 2262-i, and the reset input terminal receives the inverted (i+1)th bank precharge flag signal. The buffer gate BUF3 amplifies the signal output from the SR-type flip-flop and outputs the amplified signal as an (i+1)th bank active guard signal MCBAGi.

The (i+1)th bank active signal generation circuit 224-i is the same as that shown in FIG. 5 and thus will not explained or shown in the figures.

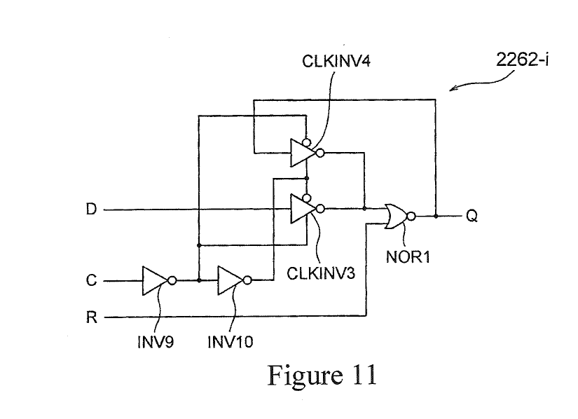

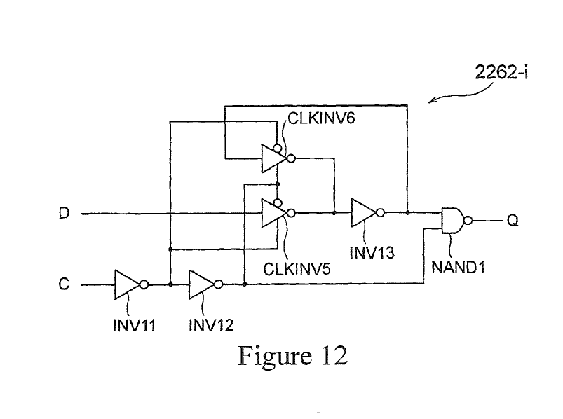

FIGS. 11 and 12 show a circuit diagram illustrating the data latch circuit 2262-i.

FIG. 11 shows a circuit diagram illustrating one example of the reset data latch circuit 2262-i. The reset data latch circuit 2262-i as this figure shows has a data input terminal D to which a data signal is input, a clock input terminal C to which a clock signal is input, a reset input terminal R to which a reset signal is input, and an output terminal Q from which an output signal is output.

The reset data latch circuit 2262-i shown in FIG. 11 consists of a first inverter INV9, a second inverter INV10, a first clocked inverter CLKINV3, a second clocked inverter CLKINV4, and an NOR gate NOR1.

The first inverter INV9 inverts the clock signal input to the clock input terminal C and outputs the inverted clock signal. The second inverter INV10 inverts the inverted clock signal and outputs the regenerated clock signal. The first clocked inverter CLKINV3 inverts the data signal input to the data input terminal and outputs the inverted data signal. The NOR gate NOR1 performs NOR on the inverted data signal and the reset signal input to the reset input terminal R and outputs the NOR result signal from the output terminal Q as an output signal. The second clocked inverter CLKINV4 inverts the NOR result signal (output signal) and outputs the inverted output signal.

FIG. 12 shows a circuit diagram illustrating another example of the data latch circuit 2262-i. The data latch circuit 2262-i as this figure shows has a data input terminal D to which a data signal is input, a clock input terminal C to which a clock signal is input, and an output terminal Q from which an output signal is output.

The data latch circuit 2262-i shown in FIG. 12 consists of a first inverter INV11, a second inverter INV12, a first clocked inverter CLKINV5, a second clocked inverter CLKINV6, a third inverter INV13, and a NAND gate NAND1.

The first inverter INV11 inverts the clock signal input to the clock input terminal C and outputs the inverted clock signal. The second inverter INV12 inverts the inverted clock signal and outputs the regenerated clock signal. The first clocked inverter CLKINV5 inverts the data signal input to the data input terminal D and outputs the inverted data signal. The third inverter INV13 inverts the inverted data signal and outputs the regenerated data signal. The second clocked inverter CLKINV6 inverts the regenerated data and outputs this inverted data signal. The NAND gate NAND1 preforms NAND on the inverted data signal and the regenerated clock signal and outputs the NAND result signal from the output terminal Q as an output signal.

The semiconductor device (1A) according to the second embodiment includes: a plurality of memory chips (200A-0 to 200A-3) commonly receiving an access command (ACT) containing chip selection information (SID) and bank address information (BA), in which

each of the plurality of memory chips (200A-0 to 200A-3) includes a control circuit (220A) reading/writing data from/to a memory bank specified by the bank address information (BA) when the chip selection information (SID) selects the memory chip itself, and

the control circuit (220A) in each of the other memory chips than the memory chip selected by the chip selection information (SID) ignores an new access command when the bank address information in the new access command is the same as the bank address information for the specified memory bank even if the new access command received before reading/writing data from/to the specified memory bank of the selected memory chip is completed contains chip selection information selecting the memory chip itself.

The control circuit (220A) of each of the other memory chips owns the bank state information (MCBAGi) on a specified memory bank in the selected memory chip and ignores a new access command while the bank state information (MCBAGi) shows that the specified memory bank in the selected memory chip is active.

Each of the plurality of memory chips (200A-0 to 200A-3) holds its own chip information and further has a chip address comparison circuit (210A) activating the chip selection control signal (MDBADT) when the chip selection information (SID) contained in an access command is the same as its own chip information.

The control circuit (220A) of the selected memory chip accesses the specified memory bank (Bank0 to Bank7) in accordance with the activated chip selection control signal (MDBADT).

The control circuit (220A) of each of the other memory chips includes control signal generation circuits (226-0 to 226-7) outputting the bank state information (MCBAGi) in response to the deactivated chip selection control signal (MDBANT).

The control signal generation circuit (226-0 to 226-7) resets the bank state information (MCBAGi) in response to the precharge command (MDDADTi) containing the bank address information (BA) for the specified memory bank.

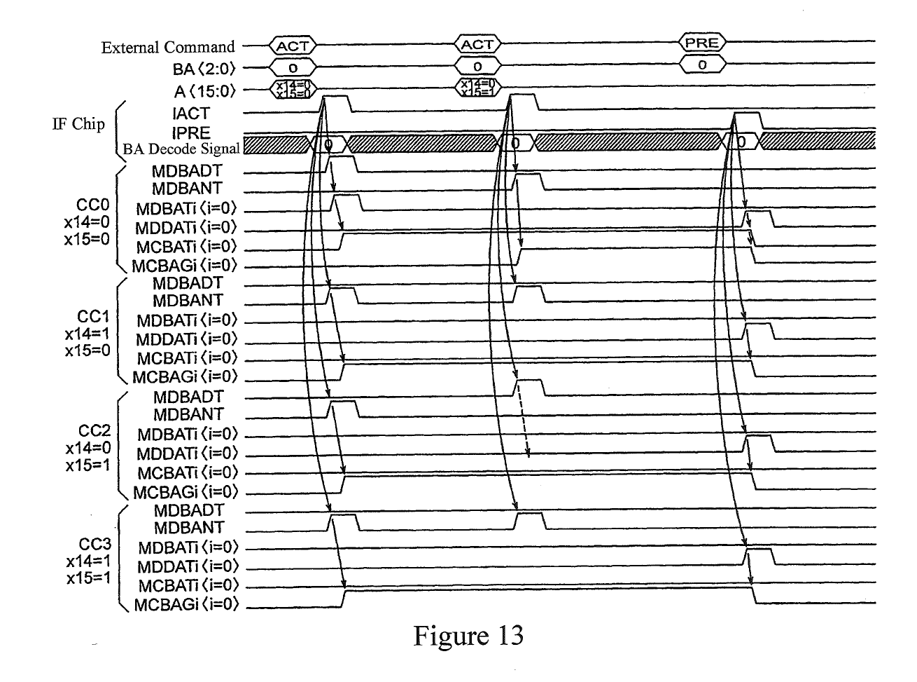

FIG. 13 shows a waveform chart explaining the operation of the semiconductor device 1A shown in FIG. 7.

For example, when the respective first memory banks Bank0 of all the first to the fourth memory chips (CC0 to CC3) 200A-0 to 200A-3 are not selected, an access command ACT containing a bank address signal BA (bank address information) specifying the first memory bank Bank0 and a chip address signal SID (chip selection information) specifying the first memory chip (CC0) 200A-0 from outside.

In this case, the semiconductor chip (IF) 100A activates an active command signal IACT in response to the access command ACT and commonly supplies the activated active command signal IACT to the first to the fourth memory chips (CC0 to CC3) 200A-0 to 200A-3.

The chip address comparison circuit 210A in the first memory chip (CC0) 200A-0 activates the main active flag signal MDBADT in response to the active command signal IACT when the chip address signal SID (chip selection information) is the same as its own chip information. Accordingly, the bank active signal generation circuit 224-0 of the bank selection control circuit 220A in the first memory chip (CC0) 200-0 activates the first bank active signal MCBAT0 to access the first memory bank Bank0.

On the other hand, the chip address comparison circuit 210A in each of the other memory chips (CC1 to CC3) 200A-1 to 200A-3 activates the auxiliary active flag signal MDBANT in response to an active command signal IACT when the chip address signal SID (chip selection information) is not the same as its own chip information. Accordingly, the bank active control circuit 180 activates the first bank active guard signal MCBAG0 in accordance with the access command ACT. Then, the bank active guard signal generation circuit 226-0 of the bank selection control circuit 220A in the other memory chips (CC1 to CC3) 200A-1 to 200A-3 activates the first bank active guard signal MCBAG0.

Next, when the first memory banks Bank0 of the first memory chip (CC0) 200-0 is selected, a new access command ACT containing a bank address signal BA (bank address information) specifying the first memory bank Bank0 and a chip address signal SID (chip selection information) specifying the third memory chip (CC2) 200-2 is input from outside before reading/writing data from/to the memory bank Bank0 of the first memory chip (CC0)200-0 is completed.

In this case, since the first bank active guard signal MCBAG0 is active in the selected third memory chip (CC2) 200-2, the first memory bank Bank0 in the third memory chip (CC2) 200-2 is not accessed in accordance with the new access command ACT. On the other hand, in the first memory chip (CC0) 200-0 with the first memory bank Bank0 being selected, the auxiliary active flag signal MDBANT is activated in response to a new access command ACT and thus the first bank active guard signal MCBAG0 is activated.

The first bank active guard signal MCBAG0 is deactivated in accordance with the precharge command signal IPRE input from outside.

### EXAMPLE 1

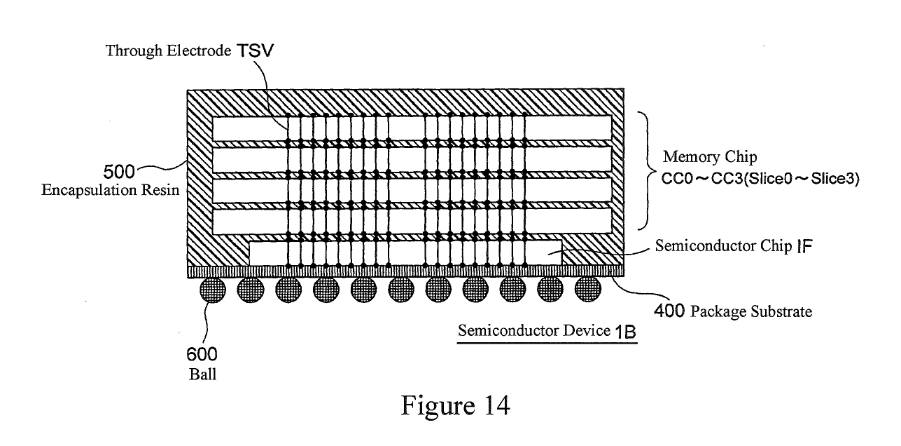

The semiconductor device 1B according to the first example of the present invention is explained in reference to FIG. 14. FIG. 14 shows a cross-sectional view illustrating the semiconductor device 1B.

The internal configuration of the semiconductor device 1B is the same as the semiconductor device 1 shown in FIG. 1 or the semiconductor device 1A shown in FIG. 7.

The semiconductor device 1B as FIG. 14 shows has a package substrate 400. The semiconductor chip IF is mounted on the principal surface of the package substrate 400. The first to fourth memory chips CC0 to CC3 are deposited on this semiconductor chip IF. Through electrodes TSV penetrates through the semiconductor chip IF and the first to the fourth memory chips CC0 to CC3. The semiconductor chip IF and the first to the fourth memory chips CC0 to CC3 are covered with encapsulation resin 500. The plurality of balls 600 are provided on the back surface of the semiconductor chip IF.

### EXAMPLE 2

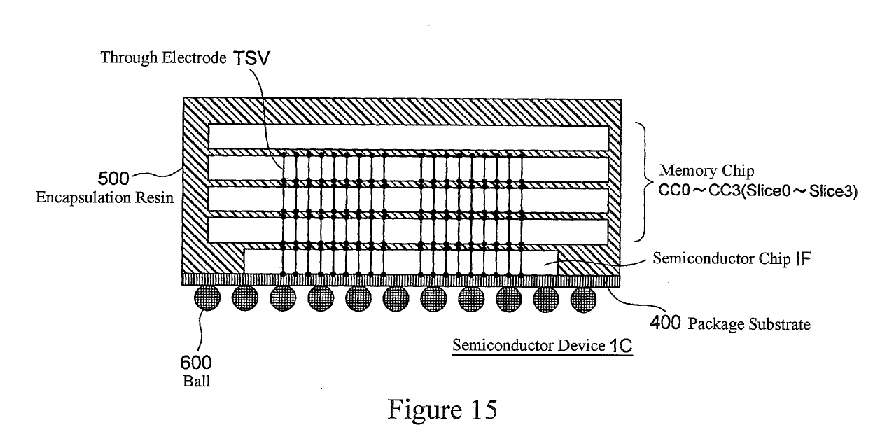

The semiconductor device 1C according to the second example of the present invention is explained below in reference to FIG. 15. FIG. 15 shows a cross-sectional view illustrating the semiconductor device 1C.

The internal configuration of the semiconductor device 1C is the same as the semiconductor device 1 shown in FIG. 1 or the semiconductor device 1A shown in FIG. 7.

The semiconductor device 1C as FIG. 15 shows has the same configuration as the semiconductor device 1B shown in FIG. 14 except for the arrangement of through electrodes TSV. Therefore, only the difference is explained below.

In the semiconductor device 1B shown in FIG. 14, each of the memory chips CC0 to CC3 has through electrodes TSV.

On the other hand, in the semiconductor device 1C shown in FIG. 15, the fourth memory chip CC3 deposited on the top does not have to transmit signals to other chips and thus has no through electrodes TSV.

The invention of the present application is explained above in reference to the embodiments (and examples) but not limited thereto. The configuration or the details of the invention of the present application can be modified in different ways that those skilled in the art understand within the scope of the invention of the present application.

### REFERENCE SIGNS LIST

1, 1A, 1B, 1C semiconductor device
100 (IF) semiconductor chip (control chip)
100A (IF) semiconductor chip (control chip)
110 address input circuit
120,130 latch circuit
140 command decoder
150 command input circuit
160 internal clock generation circuit
170 data I/O circuit
180 bank active control circuit
200-0 to 200-3(CC0 to CC3) memory chip
200A-0 to 200A-3(CC0 to CC3) memory chip
210,210-A chip address comparison circuit
212 command detection circuit
220, 220A bank selection control circuit
230 memory cell array
240 row decoder
250 column decoder
260 sense amplifier row
270-0 to 270-7 row control circuit
280 column control circuit
290 data amplifier circuit
300(TSV) through electrode
400 package substrate
500 encapsulation resin
600 ball
MC memory cell
WL word line
BL bit line
SA sense amplifier

1. A semiconductor device comprising: a plurality of memory chips commonly receiving an access command containing chip selection information and bank address information, wherein
each of the plurality of memory chips includes a control circuit reading/writing data from/to a memory bank specified by the bank address information when the chip selection information selects the memory chip itself, and
the control circuit in each of the other memory chips than the memory chip selected by the chip selection information ignores an new access command when the bank address information in the new access command is the same as the bank address information for the specified memory bank even if the new access command received before completing reading/writing data from/to the specified memory bank of the selected memory chip contains chip selection information selecting the other memory chip.

2. The semiconductor device according to claim 1, wherein the control circuit of each of the other memory chips owns the bank state information on the specified memory bank in the selected memory chip and ignores a new access command while the bank state information shows that the specified memory bank in the selected memory chip is active.

3. The semiconductor device according to claim 2, further comprising a control chip commonly outputting the access command to the plurality of memory chip, wherein
the control chip has a control signal generation circuit outputting the bank state information to the control circuit of each of the plurality of memory chips in accordance with the access command.

4. The semiconductor device according to claim 2, wherein each of the plurality of memory chips hold its own chip information and further have a chip address comparison circuit activating a chip selection control signal when the chip selection information contained in the access command is the same as its own chip information,
the control circuit of the selected memory chip accesses the specified memory bank in accordance with the activated chip selection control signal, and
the control circuit of each of the other memory chips includes a control signal generation circuit outputting the bank state information in response to the deactivated chip selection control signal.

5. The semiconductor device according to claim 1 wherein each of the plurality of memory chips has a plurality of through electrodes, and the plurality of memory chips are deposited on one another and commonly receives the access command through the plurality of through electrodes.

6. The semiconductor device according to claim 3, wherein the control chip has a plurality of first through electrodes, each of the plurality of memory chips has the plurality of second through electrodes corresponding to the plurality of first through electrodes, the control chip and the plurality of memory chips are deposited on one another, and the access command is transmitted from each of the plurality of first through electrodes of the control chip to the corresponding one of the plurality of second through electrodes of each of the plurality of memory chips.

7. The semiconductor device according to claim 2, wherein the control signal generation circuit resets the bank state information in accordance with the precharge command containing bank address information for the specified memory bank.

8. A semiconductor device comprising: a first and a second memory chips commonly receiving an access command containing chip selection information and bank address information, the first and the second memory chips being deposited on one another, wherein
each of the first and the second memory chips has a predetermined memory bank including a plurality of word lines, the predetermined memory bank being specified from a predetermined bank address information,
the first memory chip has a control circuit activating a word line selected from the plurality of word lines in the predetermined memory bank in accordance with a first access command containing chip information selecting the first memory chip and the predetermined bank address information, the first access command being supplied when the plurality of word lines in the predetermined memory bank of the second memory chip are inactive, and
the second memory chip has a control circuit remaining the plurality of word lines in the predetermined memory bank inactive if receiving a second access command containing chip contains chip information selecting the second memory chip and the predetermined bank address information, the first access command being supplied while the selected word line in the predetermined memory bank of the first memory chip is being active.
